(19) United States
(12) Patent Application Publication
(10) Pub. No.: US 2024/0047629 A1
(43) Pub. Date: Feb. 8, 2024

(54) DISPLAY PANEL AND MANUFACTURING METHOD THEREOF

(71) Applicants: Huizhou China Star Optoelectronics Display Co., Ltd., Huizhou (CN); TCL China Star Optoelectronics Technology Co., Ltd., Shenzhen (CN)

(72) Inventor: Kai Zhou, Huizhou (CN)

(21) Appl. No.: 17/619,576

(22) PCT Filed: Nov. 23, 2021
(86) PCT No.: PCT/CN2021/132454

§ 371 Date: Dec. 15, 2021

(30) Foreign Application Priority Data
Nov. 10, 2021 (CN) 202111328835.6

(51) Int. Cl. H01L 33/60; H01L 25/16

(52) U.S. Cl. CPC H01L 33/60; H01L 25/167; H01L 2933/0058

(57) ABSTRACT

A display panel and a manufacturing method thereof are provided. The display panel includes an array substrate, light emitting chips, and a light reflecting layer. The light emitting chips are disposed on the array substrate; and the light reflecting layer is disposed on the array substrate and surrounds the light emitting chips. The light reflecting layer gathers light emitted from side surfaces of the light emitting chips and emits the light from top surfaces of the light emitting chips, thereby improving the light emission efficiency of the light emitting chips and increasing the front display brightness of the display panel.

### BACKGROUND

### Technical Field

The present invention relates to the field of display devices, and in particular, to a display panel and a manufacturing method thereof.

### Related Art

With the iterative development of display technologies, the conventional liquid crystal display (LCD) industry is facing severe challenges. Currently, numerous enterprises successively deploy the development of cutting-edge display technologies such as an active-matrix organic light-emitting diode (AMOLED) technology and a micro-light emitting diode (micro-LED) technology. The micro-LED technology is regarded as an ultimate display technology for its advantages such as high contrast, high brightness, long service life, and a low cost. A micro-LED is essentially an integrated point light source, and has an obvious point light source characteristic during light emission. Because light is emitted from side surfaces, most light is not effectively utilized. A solution is required to resolve this problem.

A relatively high cost is incurred when a side-surface light blocking layer is manufactured in a process of manufacturing an array substrate, and the process complexity in the process of manufacturing the array substrate is increased, affecting the yield of the array substrate. In addition, lamp bead transfer is one of the most important links in the whole micro-LED display technology, and a light blocking film layer in the process of manufacturing the array substrate greatly affects the transfer yield.

### Technical Problems

An objective of the present invention is to provide a display panel and a manufacturing method thereof, to resolve technical problems in the related art that most light is not effectively utilized because light is emitted from side surfaces of a micro-LED and a side-surface light blocking layer has a relatively high manufacturing cost and a complex process.

### SUMMARY

### Technical Solutions

To achieve the foregoing objective, the present invention provides a display panel. The display panel includes an array substrate, light emitting chips, and a light reflecting layer. The light emitting chips are disposed on the array substrate. The light reflecting layer is disposed on the array substrate and surrounds side surfaces of the light emitting chips.

Further, the display panel further includes a light blocking layer disposed between the light emitting chips and the array substrate.

Further, the light blocking layer covers a surface of the array substrate facing the light emitting chips. The light emitting chips are disposed on the light blocking layer and are electrically connected to the array substrate.

Further, the light reflecting layer comprises an insulating material.

Further, a thickness of the light reflecting layer is less than a thickness of each light emitting chip.

Further, a horizontal plane in which a top surface of the light reflecting layer is located is lower than a horizontal plane in which top surfaces of the light emitting chips are located.

Further, the array substrate comprises thin film transistors, and the light emitting chips are electrically connected to the thin film transistors.

The present invention further provides a manufacturing method of a display panel. The manufacturing method includes following steps: forming light emitting chips on an array substrate; providing a mask, where the mask comprises shielded areas and a hollowed-out area; and forming, by the mask, a light reflecting layer surrounding the light emitting chips on the array substrate, where the shielded areas of the mask correspond to the light emitting chips, and the hollowed-out area corresponds to the light reflecting layer.

Further, before the step of forming light emitting chips on an array substrate, the method further comprises: forming a light blocking layer on the array substrate.

Further, the mask has the shielded areas and the hollowed-out area surrounding the shielded areas, the shielded areas correspond to the light emitting chips, and the hollowed-out area corresponds to the light reflecting layer.

### Beneficial Effects

Advantages of the present invention are as follows: In a display panel and a manufacturing method thereof provided in the present invention, a light reflecting layer is manufactured on side surfaces of light emitting chips, to prevent light from being emitted from the side surfaces of the light emitting chips, so that light emitted by the light emitting chips is gathered and emitted from top surfaces of the light emitting chips, thereby increasing the front display brightness of the display panel. In addition, the display panel has a simple manufacturing process and a readily available material, thereby reducing a production cost without further affecting the transfer yield of the light emitting chips.

### BRIEF DESCRIPTION OF THE DRAWINGS

To describe the technical solutions in embodiments of the present invention more clearly, the following briefly describes the accompanying drawings required for describing the embodiments. Apparently, the accompanying drawings in the following description show merely some embodiments of the present invention, and a person skilled in the art may still derive other drawings from these accompanying drawings without creative efforts.

FIG. 1 is a schematic diagram of a layered structure of a display panel in an embodiment of the present invention;

FIG. 2 is an enlarged schematic diagram of the layered structure of the display panel in a dashed-line box A in FIG. 1;

FIG. 3 is a schematic flowchart of a manufacturing method of a display panel in an embodiment of the present invention;

FIG. 4 is a schematic diagram of a layered structure of a display panel after step S10 in an embodiment of the present invention;

FIG. 5 is a schematic diagram of a layered structure of a display panel after step S20 in an embodiment of the present invention; and

FIG. 6 is a schematic planar diagram of a mask in an embodiment of the present invention.

Components in the figures are represented as follows:
display panel 1;
array substrate 10;
substrate layer 101;
light shielding layer 102;
buffer layer 103;
active layer 104;
gate insulating layer 105;
gate layer 106;
dielectric layer 107;
source-drain layer 108;
passivation layer 109;
planarization layer 110;
pixel electrode layer 111;
light blocking layer 20;
light emitting chip 30;
light reflecting layer 40;
mask 2;
shielded area 201;
hollowed-out area 202;
first surface S1;
second surface S2; and
third surface S3.

### DESCRIPTION OF THE PRESENT INVENTION

The following describes preferred embodiments of the present invention with reference to the accompanying drawings of this specification, to prove that the present invention can be implemented. The present invention may be completely described for a person skilled in the art by using the embodiments of the present invention, so that the technical content is clearer and easier to understand. The present invention can be embodied in many different forms of embodiments of the present invention, and the protection scope of the present invention is not limited to the embodiments mentioned in this specification.

In the accompanying drawings, components with the same structure are represented by the same numerals, and components with similar structures or functions are represented by similar numerals. A size and thickness of each component shown in the accompanying drawings are arbitrarily shown, and the size and thickness of each component are not limited in the present invention. To make the accompanying drawings clearer, the thicknesses of the components are appropriately exaggerated in some places in the accompanying drawings.

In addition, description of the following embodiments of the present invention is provided to exemplify the specific embodiments of the present invention that can be implemented in the present invention with reference to attached accompanying drawings. The directional terms mentioned in the present invention, for example, “above”, “below”, “front”, “rear”, “left”, “right”, “inside”, “outside” and “side surface” merely refer to directions in the attached accompanying drawings. Therefore, the used directional terms are for better and clearer description and understanding of the present invention, rather than indicating or implying that a mentioned apparatus or element needs to have a particular orientation or be constructed and operated in a particular orientation, and therefore should not be construed as a limitation on the present invention. In addition, terms such as “first”, “second” and “third” are only used for description purpose and cannot be construed as indicating or implying relative importance.

When a specific component is described as being “above” another component, the component may be directly disposed on the another component; alternatively, there may be an intermediate component, the component is disposed on the intermediate component, and the intermediate component is disposed on another component. When a component is described as being “mounted to” or “connected to” another component, both may be understood as being directly “mounted” or “connected”, or a component is indirectly “mounted to” or “connected to” another component by an intermediate component.

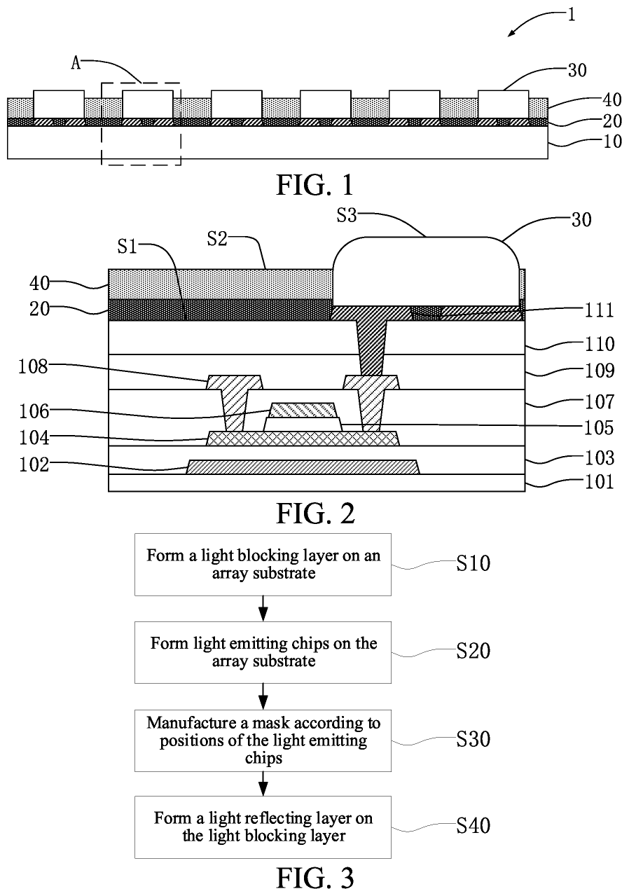

An embodiment of the present invention provides a display device. The display device includes a display panel 1. The display panel 1 is used for providing a display screen to the display device. The display device may be any electronic product or component with a display function. As shown in FIG. 1 and FIG. 2, the display panel 1 includes an array substrate 10, a light blocking layer 20, light emitting chips 30, and a light reflecting layer 40.

The array substrate 10 includes a plurality of thin film transistors and a base layer. The thin film transistors are arranged in an array on the base layer. Each thin film transistor includes a conductive structure and an insulating structure. The conductive structure includes an active layer 104, a gate layer 106, and a source-drain layer 108. The insulating structure includes a gate insulating layer 105, a dielectric layer 107, a passivation layer 109, a planarization layer 110, and the like.

The active layer 104 is disposed on the base layer. The gate insulating layer 105 is disposed on the active layer 104. The gate layer 106 is disposed on the gate insulating layer 105. The dielectric layer 107 is disposed on the base layer and covers the active layer 104, the gate insulating layer 105, and the gate layer 106. The source-drain layer 108 is disposed on the dielectric layer 107, and is electrically connected to the active layer 104 by the dielectric layer 107. The passivation layer 109 is disposed on the dielectric layer 107 and covers the source-drain layer 108. The planarization layer 110 is disposed on the passivation layer 109.

The base layer includes a substrate layer 101, a light shielding layer 102, and a buffer layer 103. The light shielding layer 102 is disposed on the substrate layer 101 and is disposed corresponding to the active layer 104. The buffer layer 103 is disposed on the substrate layer 101 and covers the light shielding layer 102. The active layer 104 is disposed on a surface of the buffer layer 103 away from the light shielding layer 102.

The light shielding layer 102 generally includes an opaque metal material, and is used for shielding the active layer 104 from light, to prevent the light from affecting the operation of the active layer 104. The buffer layer 103 and an insulating structure layer generally include inorganic materials such as silicon oxide and silicon nitride. The buffer layer 103 and the insulating structure layer are used for insulating and protecting conductive lines in the thin film transistors, to prevent a short circuit between the lines. The planarization layer 110 is further used for planarizing surfaces of the thin film transistors.

The array substrate 10 further includes a pixel electrode layer 111 disposed on the planarization layer 110, and electrically connected to the source-drain layer 108 by the planarization layer 110 and the passivation layer 109.

The light blocking layer 20 is disposed on the planarization layer 110 of the array substrate 10 and covers an exposed surface of the planarization layer 110. The light blocking layer 20 includes a photoresist material with a light shielding property. The light blocking layer 20 can prevent light emitted by the light emitting chips 30 from leaking out from a side of the array substrate 10. The light blocking layer 20 includes a plurality of openings, and the openings correspond to the pixel electrode layer 111, so that a surface of the pixel electrode layer 111 away from the planarization layer 110 is exposed.

The light emitting chips 30 are disposed in the openings, and are electrically connected to the pixel electrode layer 111 in the openings. The light emitting chips 30 are electrically connected to the thin film transistors in the array substrate 10 by the pixel electrode layer 111, to obtain electric energy and implement self-light emission. Each light emitting chip 30 may be one of a self-light emitting chip 30 such as a mini-light emitting diode (mini-LED) and a micro-LED. The light emitting chip 30 may emit any of white light, red light, blue light, and green light. When all the light emitting chips 30 in the display panel 1 emit the same color, filtering and conversion of a light color may be implemented by using a color filter, thereby implementing color display. When the light emitting chips 30 in the display panel 1 separately emit light of different colors, color display can be directly implemented.

The light reflecting layer 40 is disposed on a surface of the light blocking layer 20 away from the array substrate 10, and surrounds side surfaces of the light emitting chips 30. The light reflecting layer 40 includes a reflective insulating material, such as a polyester material or resin material doped with a reflective material. The light reflecting layer 40 is used for preventing light from being emitted from the side surfaces of the light emitting chips 30, gathers the light, and emits the gathered light from top surfaces of the light emitting chips 30, thereby reducing the waste of the light and improving the light emission efficiency of the light emitting chips 30. In some embodiments, the light reflecting layer 40 may be, for example, in direct contact with and cover peripheral side surfaces of the light emitting chips 30, or maintain a gap distance with the peripheral side surfaces of the light emitting chips 30 to implement particular shielding. In some embodiments, the light reflecting layer 40 may further include an insulating material with a better heat dissipation property.

A surface of the array substrate 10 facing the light emitting chips 30 and the light reflecting layer 40 is a first surface S1, a surface of the light reflecting layer 40 away from the array substrate 10 is a second surface S2, and a surface of the light emitting chips 30 away from the array substrate 10 is a third surface S3. To prevent the light reflecting layer 40 from affecting front light emission of the display panel 1, a thickness of the light reflecting layer 40 is less than a thickness of each light emitting chip 30 and is greater than a half of the thickness of the light emitting chip 30, and a distance between the first surface S1 and the second surface S2 is less than a distance between the first surface S1 and the third surface S3. That is, a horizontal plane in which a top surface of the light reflecting layer 40 is located is lower than a horizontal plane in which top surfaces of the light emitting chips 30 are located, thereby preventing the light reflecting layer 40 from covering light-outgoing top surfaces of the light emitting chips 30. Specifically, the second surface S2 is located at a position higher than 50% of a height of each light emitting chip 30, and preferably, is located at 75% of the height of the light emitting chip 30.

An embodiment of the present invention further provides a manufacturing method of a display panel 1, used for manufacturing the display panel 1 described above. A specific procedure of the manufacturing method is shown in FIG. 3, and includes following steps:

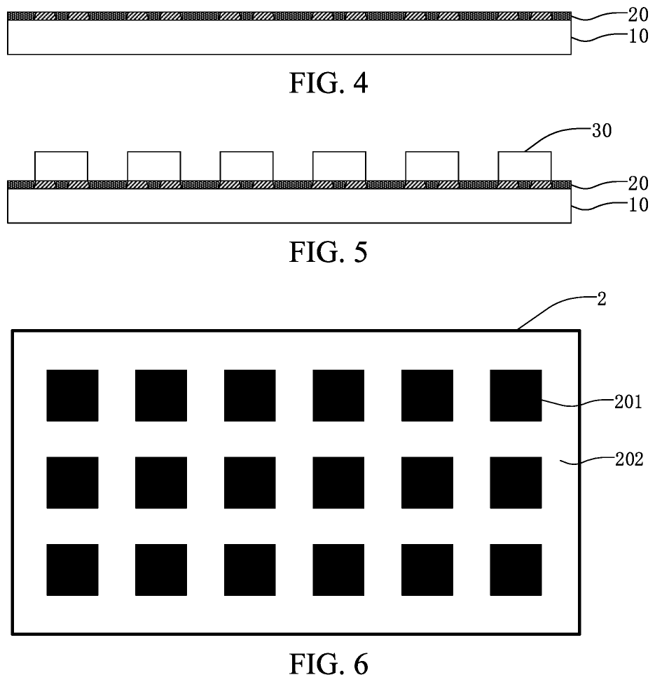

Step S10). Form a light blocking layer 20 on an array substrate 10: forming a plurality of thin film transistors and a pixel electrode layer 111 on a base layer by using a process of manufacturing thin film transistors, to form the array substrate 10. The light blocking layer 20 shown in FIG. 4 is formed on the array substrate 10 by using a photolithography process.

Step S20). Form light emitting chips 30 on the array substrate 10: gathering a plurality of light emitting chips 30 together in an array according to a sequence, and transferring the light emitting chips 30 to the array substrate 10 through a mass transfer, to form the structure shown in FIG. 5.

Step S30). Manufacture a mask 2 according to positions of the light emitting chips 30: manufacturing a mask material, and forming shielded areas 201 and a hollowed-out area 202 on the mask according to positions of the light emitting chips 30 on the array substrate 10, to form the mask 2. As shown in FIG. 6, the shielded areas 201 correspond to the light emitting chips 30, and a remaining area of the mask 2 other than the shielded areas 201 is the hollowed-out area 202. Each shielded area 201 is of a fully sealed structure and does not allow the permeation of a printing material. The hollowed-out area 202 is of a mesh structure and includes a plurality of through holes that allow the permeation of a printing material. Specifically, the hollowed-out area 202 may include a wire mesh made of a metal mesh, a nylon mesh, or the like.

Step S40): Form a light reflecting layer 40 on the light blocking layer 20: performing an alignment operation on the mask 2 and the array substrate 10, and making the shielded areas 201 in the mask 2 correspond to the light emitting chips 30. Through the mask 2, the light blocking layer 20 is coated with an insulating glue material doped with a reflective material. After the coating is completed, the coated insulating glue material is cured through baking or ultraviolet irradiation, to form the light reflecting layer 40, to complete the manufacturing of the display panel 1.

In the display panel and the manufacturing method thereof provided in the embodiments of the present invention, a light reflecting layer is manufactured on side surfaces of light emitting chips, and light is shielded from scattering from the side surfaces of the light emitting chips by using the light reflecting layer, so that light emitted by the light emitting chips is gathered and emitted from top surfaces of the light emitting chips, thereby improving the light emission efficiency of the light emitting chips, and further increasing the front display brightness of the display panel. In addition, in the manufacturing method provided in the embodiments of the present invention, a light reflecting layer is manufactured by using a screen printing process after the light emitting chips are transferred, and has a readily available raw material and a simple process, thereby reducing a production cost and further ensuring the transfer yield of the light emitting chips.

Although the present invention is described in this specification with reference to specific implementations, it should be understood that the embodiments are merely examples of the principles and applications of the present invention. Therefore, it should be understood that many modifications may be made to the exemplary embodiments, and other arrangements may be designed, provided that the spirit and scope of the present invention defined by the appended claims are not departed. It should be understood that different dependent claims and the features described in this specification can be combined in a manner different from that described in original claims. It may be further understood that the features described in combination with a separate embodiment may be used in other described embodiments.

What is claimed is:

1. A display panel, comprising:
an array substrate;
a plurality of light emitting chips disposed on the array substrate; and
a light reflecting layer disposed on the array substrate, and surrounding side surfaces of the light emitting chips.

2. The display panel according to claim 1, further comprising:
a light blocking layer disposed between the light emitting chips and the array substrate.

3. The display panel according to claim 2, wherein
the light blocking layer covers a surface of the array substrate facing the light emitting chips; and
the light emitting chips are disposed on the light blocking layer and are electrically connected to the array substrate.

4. The display panel according to claim 1, wherein the light reflecting layer comprises an insulating material.

5. The display panel according to claim 1, wherein a thickness of the light reflecting layer is less than a thickness of each light emitting chip.

6. The display panel according to claim 1, wherein a horizontal plane in which a top surface of the light reflecting layer is located is lower than a horizontal plane in which top surfaces of the light emitting chips are located.

7. The display panel according to claim 1, wherein the array substrate comprises thin film transistors, and the light emitting chips are electrically connected to the thin film transistors.

8. A manufacturing method of a display panel, wherein the method comprises following steps:
forming light emitting chips on an array substrate;
providing a mask, wherein the mask comprises shielded areas and a hollowed-out area; and
forming, using the mask, a light reflecting layer surrounding the light emitting chips on the array substrate, wherein the shielded areas of the mask correspond to the light emitting chips, and the hollowed-out area corresponds to the light reflecting layer.

9. The manufacturing method of a display panel according to claim 8, wherein before the step of forming light emitting chips on an array substrate, the method further comprises following step:
forming a light blocking layer on the array substrate.

10. The manufacturing method of a display panel according to claim 8, wherein the mask has the shielded areas and the hollowed-out area surrounding the shielded areas, the shielded areas correspond to the light emitting chips, and the hollowed-out area corresponds to the light reflecting layer.
